(19) United States
(12) Patent Application Publication
(10) Pub. No.: US 2026/0181776 A1
(43) Pub. Date: Jun. 25, 2026

(54) WIRING BOARD AND MOUNT STRUCTURAL BODY

(71) Applicant: KYOCERA CORPORATION, Kyoto-shi (JP)

(72) Inventors: Chihiro NISHIMOTO, Ayabe-shi (JP); Daichi SHIMIZU, Maizuru-shi (JP)

(73) Assignee: KYOCERA CORPORATION, Kyoto-shi (JP)

(21) Appl. No.: 19/422,865

(22) Filed: Dec. 17, 2025

(30) Foreign Application Priority Data
Dec. 25, 2024 (JP) 2024-228349

(51) Int. Cl. H05K 1/11; H05K 1/02

(52) U.S. Cl. CPC H05K 1/116; H05K 1/0298

(57) ABSTRACT

A wiring board includes: a first insulating layer including a first surface; a conductor layer positioned on the first surface and at least including a land conductor; a second insulating layer positioned on the first surface, including a second surface positioned opposite to the first insulating layer, and including a via hole penetrating from the second surface to the land conductor; and a via hole conductor positioned in the via hole and being in contact with the land conductor. The land conductor includes a first region in contact with the via hole conductor, and a second region other than the first region. The second region and the second insulating layer interpose an organic film.

### BACKGROUND OF THE INVENTION

### FIELD OF THE INVENTION

The present invention relates to a wiring board and a mount structural body including the wiring board.

### DESCRIPTION OF THE RELATED ART

As described in Japanese Unexamined Patent Application Publication No. 2023-180974, a wiring board has a structure including insulating layers and conductor layers stacked alternatively. The insulating layers each include a via hole provided with a via hole conductor for electrical connection between the conductor layers positioned at different layer levels. The via hole conductor is typically connected to a land conductor included in each of the conductor layers.

Intimate contact properties between an insulating layer and a conductor layer has been conventionally improved by forming an organic film between the insulating layer and the conductor layer without coarsening wiring (or with decreased coarsening) for reduced deterioration of electrical characteristics due to a skin effect. Furthermore, in a via hole portion, a land conductor is provided with a concave portion larger in diameter than a bottom of a via hole and a via hole conductor is formed for achievement of firm connection between the land conductor and the via hole conductor. The organic film formed on a bottom portion of the via hole is removed by a laser beam applied during formation of the via hole. However, the laser beam does not remove the organic film formed on the insulating layer extending to the concave portion. Plating is less likely to adhere to the organic film, and the insulating layer extending to the concave portion has small surrounding clearance. This disturbs circulation of a plating solution and growth of plating. The via hole conductor thus exhibits poor electrical reliability in a wiring board.

### SUMMARY OF THE INVENTION

The present invention provides a wiring board improved in the electrical reliability of a via hole conductor without affecting intimate contact properties between a land conductor and an insulating layer.

The present disclosure provides a wiring board including a first insulating layer, a conductor layer, a second insulating layer, and a via hole conductor. The first insulating layer includes a first surface. The conductor layer is positioned on the first surface and at least includes a land conductor. The second insulating layer is positioned on the first surface, includes a second surface positioned opposite to the first insulating layer, and includes a via hole penetrating from the second surface to the land conductor. The via hole conductor is positioned in the via hole and is in contact with the land conductor. The land conductor includes a first region in contact with the via hole conductor, and a second region other than the first region. The second region and the second insulating layer interpose an organic film.

The present disclosure provides a mount structural body including the wiring board described above, and an electronic component connected to the wiring board.

In the present disclosure, the wiring board is configured as described above and is thus improved in the electrical reliability of the via hole conductor without affecting intimate contact properties between the land conductor and the insulating layer.

### BRIEF DESCRIPTION OF THE DRAWINGS

FIG. 1 is an explanatory view of a wiring board according to an embodiment of the present disclosure;

FIG. 2 is an enlarged explanatory view of a region II indicated in FIG. 1 according to an embodiment; and

FIG. 3 is an enlarged explanatory view of a region III indicated in FIG. 2 according to an embodiment.

### DESCRIPTION OF THE PREFERRED EMBODIMENTS

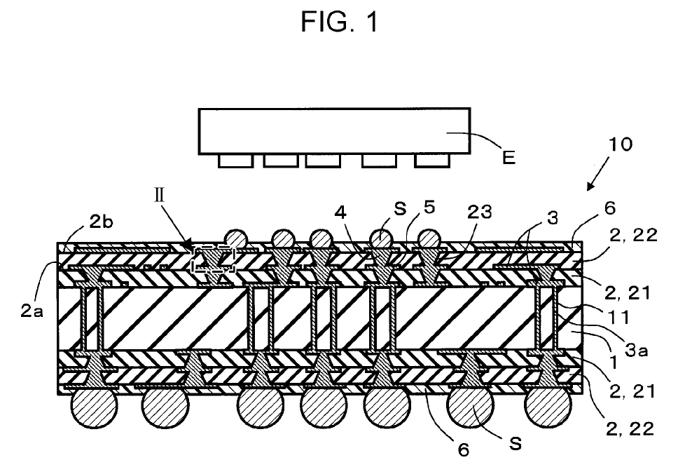

Description is made to a wiring board according to an embodiment of the present disclosure with reference to FIGS. 1 to 3. FIG. 1 is an explanatory view of a wiring board 10 according to an embodiment of the present disclosure. As illustrated in FIG. 1, in an embodiment, the wiring board 10 includes a core insulating layer 1, a buildup insulating layer 2 (a first insulating layer 21 and a second insulating layer 22), a conductor layer 3 (a core conductor layer and a buildup conductor layer), and a solder resist 6.

The core insulating layer 1 is positioned substantially in the center in a thickness direction of the wiring board 10. The core insulating layer 1 is not particularly limited as long as the core insulating layer 1 is made of an insulating material. Examples of such an insulating material include resins such as epoxy resin, bismaleimide triazine resin, polyimide resin, and polyphenylene ether resin, as well as glass. The core insulating layer 1 may be made of only one of these insulating materials, or may be made of two or more of these insulating materials.

The core insulating layer 1 is not particularly limited in thickness, and is exemplarily 40 μm or more and 2000 μm or less in thickness. The core insulating layer 1 is not an essential member. For example, a substrate called a coreless substrate includes no core insulating layer 1.

The core insulating layer 1 may contain a reinforcer. Examples of the reinforcer include insulating fabric materials such as glass fiber, glass nonwoven fabric, aramid nonwoven fabric, aramid fiber, and polyester fiber. The core insulating layer 1 may contain only one of these reinforcers, or may contain two or more of these reinforcers. The core insulating layer 1 may further contain an insulating filler such as silica, barium sulfate, talc, clay, glass, calcium carbonate, or titanium oxide. The core insulating layer 1 may contain only one of these insulating fillers, or may contain two or more of these insulating fillers.

The core insulating layer 1 includes both surfaces each provided with the core conductor layer. The core conductor layer constitutes the conductor layer 3 positioned on each of the surfaces of the core insulating layer 1. The core conductor layer is not limited as long as the core conductor layer is made of a conductive material. Examples of the conductive material include a metal such as copper. The core conductor layer is not particularly limited in thickness, and is exemplarily 1 μm or more and 30 μm or less in thickness. The core conductor layer is positioned on each of the surfaces of the core insulating layer 1 in FIG. 1. Alternatively, the core conductor layer has only to be positioned on at least one of the surfaces of the core insulating layer 1.

As illustrated in FIG. 1, the core insulating layer 1 is provided with a through-hole conductor 3a for electrical connection between upper and lower surfaces of the core insulating layer 1. The through-hole conductor 3a is positioned in a through-hole 11 penetrating from the upper surface to the lower surface of the core insulating layer 1. The through-hole conductor 3a contains a metal such as copper. The through-hole conductor 3a is connected to the core conductor layer provided on each of the surfaces of the core insulating layer 1. The through-hole conductor 3a may be formed integrally with the core conductor layer. Alternatively, the through-hole conductor 3a may be positioned only on an inner wall surface of the through-hole 11, or may be filled in the through-hole 11.

As illustrated in FIG. 1, the core insulating layer 1 and the core conductor layer are included in a core layer that includes both surfaces each provided with a buildup layer. The buildup layer has a structure including buildup insulating layers 2 and buildup conductor layers stacked alternatively. Each of the buildup insulating layers 2 includes the first insulating layer 21 and the second insulating layer 22. Each of the buildup conductor layers constitutes the conductor layer 3 positioned on surfaces of the first insulating layer 21 and the second insulating layer 22.

The buildup layer is provided with two buildup insulating layers 2 in FIG. 1.

Alternatively, the buildup layer may be provided with two or more buildup insulating layers 2. The present specification defines that two buildup insulating layers 2 adjacent to each other include the “first insulating layer 21” close to the core insulating layer 1 and the “second insulating layer 22” far from the core insulating layer 1.

The first insulating layer 21 includes a first surface 2a. Between surfaces of the first insulating layer 21, the first surface 2a is positioned far from the core insulating layer 1. The second insulating layer 22 includes a second surface 2b. Between surfaces of the second insulating layer 22, the second surface 2b is positioned opposite to the first insulating layer 21. When the core insulating layer 1 and the buildup insulating layer 2 constitute two adjacent layers, the core insulating layer 1 may be regarded as the “first insulating layer 21”.

The buildup insulating layer 2 is not particularly limited as long as the buildup insulating layer 2 is made of an insulating material. Examples of such an insulating material include resins such as epoxy resin, bismaleimide triazine resin, polyimide resin, and polyphenylene ether resin. The insulating material may contain only one of these resins, or may contain two or more of these resins. The buildup layer is positioned on each of the surfaces of the core layer in FIG. 1. Alternatively, the buildup layer has only to be positioned on at least one of the surfaces of the core layer.

The buildup insulating layers 2 may be made of a same resin, or may be made of different resins. The buildup insulating layers 2 and the core insulating layer 1 may be made of a same resin, or may be made of different resins. Each of the buildup insulating layers 2 is not particularly limited in thickness, and is exemplarily 10 μm or more and 100 μm or less in thickness. The buildup insulating layers 2 may be identical or different in thickness.

Each of the buildup insulating layers 2 may contain a reinforcer. Examples of the reinforcer include insulating fabric materials such as glass fiber, glass nonwoven fabric, aramid nonwoven fabric, aramid fiber, and polyester fiber. The buildup insulating layer 2 may contain only one of these reinforcers, or may contain two or more of these reinforcers. The buildup insulating layer 2 may further contain an insulating filler such as silica, barium sulfate, talc, clay, glass, calcium carbonate, or titanium oxide.

The core insulating layer 1 may contain only one of these insulating fillers, or may contain two or more of these insulating fillers.

The buildup insulating layer 2 includes surfaces each provided with the buildup conductor layer. The buildup conductor layer constitutes the conductor layer 3 positioned on each of the surfaces of the buildup insulating layer 2. The buildup conductor layer is not particularly limited as long as the buildup conductor layer is made of a conductive material. Examples of the conductive material include a metal such as copper. The buildup conductor layer is not limited in thickness, and is exemplarily 1 μm or more and 40 μm or less in thickness.

The buildup conductor layers may be made of a same metal, or may be made of different metals. Each of the buildup conductor layers and the core conductor layer may be made of a same metal, or may be made of different metals. Moreover, the buildup conductor layers may be identical or different in thickness.

Each of the buildup insulating layers 2 is provided with a via hole conductor 4 for electrical connection between upper and lower surfaces of the buildup insulating layer 2. Specifically, in two adjacent buildup insulating layers 2, the via hole conductor 4 is positioned in a via hole 23 penetrating from the second surface 2b of the second insulating layer 22 to a land conductor 5 positioned on the first surface 2a of the first insulating layer 21.

The land conductor 5 and the via hole conductor 4 are part of the conductor layer 3.

As illustrated in FIG. 1, the buildup layer includes a surface that may be provided with the solder resist 6. The solder resist 6 is made of a resin, examples of which include an acrylic modified epoxy resin. The solder resist 6 is provided with an opening for electrical connection between the conductor layer 3 and an electrode of an electronic component E via a solder S. Examples of the electronic component E include a semiconductor integrated circuit and an optoelectronic element.

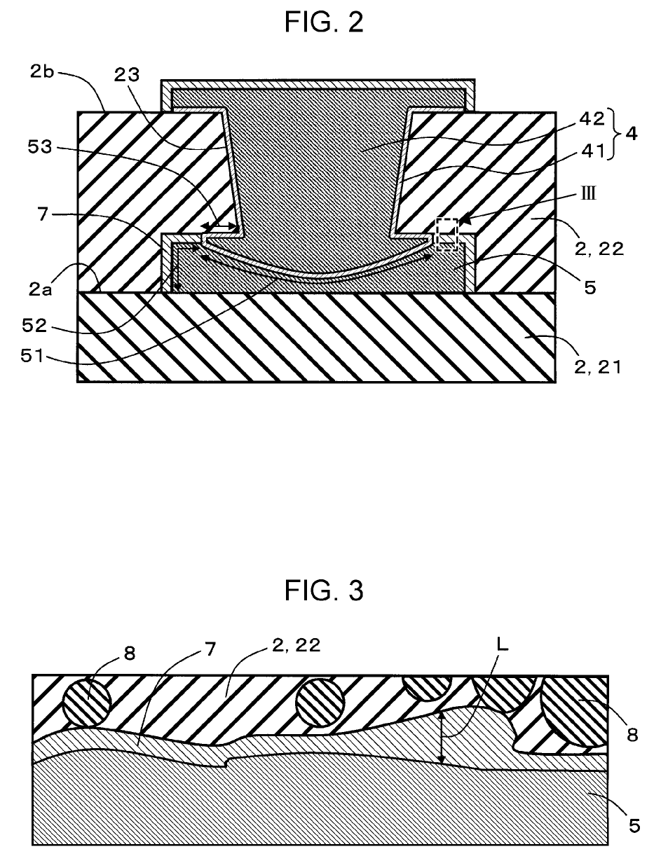

As illustrated in FIG. 2, the via hole conductor 4 may include, for example, a first conductor layer 41 and a second conductor layer 42. FIG. 2 is an enlarged explanatory view of a region II indicated in FIG. 1 according to an embodiment. The first conductor layer 41 functions as a ground metal layer or the like. The first conductor layer 41 is formed by sputtering, electroless plating, or the like. The first conductor layer 41 contains copper or the like. The first conductor layer 41 is not limited in thickness, and may be exemplarily 0.05 μm or more and 2.00 μm or less in thickness.

The second conductor layer 42 constitutes a principal part of the via hole conductor 4. The second conductor layer 42 is formed by electroplating or the like. The second conductor layer 42 contains copper or the like.

As illustrated in FIG. 2, the via hole conductor 4 is in contact with the land conductor 5. Specifically, the land conductor 5 includes a first region 51, and a second region 52 as a region other than the first region 51. The first region 51 is in contact with the via hole conductor 4. The second region 52 corresponds to a region other than the first region 51 as described above, and is not provided with the via hole conductor 4. In other words, the second region 52 is regarded as a region not in contact with the via hole conductor 4 or the first insulating layer 21 in the land conductor 5.

The second region 52 includes a surface on which the land conductor 5 faces the second insulating layer 22 and on which an organic film 7 is positioned as illustrated in FIG. 2. The organic film 7 is not positioned in the first region 51. Such a structure leads to provision of the wiring board 10 that achieves excellent intimate contact properties between the land conductor 5 and the second insulating layer 22 and high electrical reliability between the via hole conductor 4 and the land conductor 5. The organic film 7 is not limited. The organic film 7 is made of a material, examples of which include a silane coupling agent.

The surface of the second region 52 has arithmetic mean roughness that is not limited but is preferred to be relatively small in view of electrical signal transmission performance. The surface of the second region 52 may have arithmetic mean roughness of exemplarily 100 nm or more and 200 nm or less.

As illustrated in FIG. 2, the first region 51 of the land conductor 5 may include a concave portion shaped to be concave toward the first surface 2a of the first insulating layer 21. The first region 51 including the concave portion advantageously increases a contact area between the via hole conductor 4 and the land conductor 5 to improve connection strength therebetween.

The conductor layer 3 may further include a wiring conductor disposed on the first surface 2a. The wiring conductor includes a surface having arithmetic mean roughness that is not limited but is preferred to be relatively small in view of electrical signal transmission performance. The surface of the wiring conductor may have arithmetic mean roughness of exemplarily 100 nm or more and 200 nm or less.

Moreover, the organic film 7 thus positioned improves intimate contact properties between the conductor layer 3 and the insulating layer. The organic film 7 may therefore be positioned also on a surface of the conductor layer 3 (a power source conductor, a ground conductor, or the like) in a region other than the second region 52 of the land conductor 5.

The via hole conductor 4 includes a side surface not limited in arithmetic mean roughness. The side surface of the via hole conductor 4 may be larger in arithmetic mean roughness than the surface of the second region 52. Such a configuration achieves firm intimate contact between the second insulating layer 22 and the side surface of the via hole conductor 4 that is likely to receive larger stress than the second region 52 of the land conductor 5 in a thickness direction or the like of the wiring board 10. The side surface of the via hole conductor 4 may have arithmetic mean roughness of exemplarily 100 nm or more and 1000 nm or less. The side surface of the via hole conductor 4 is measured by means of a white light interferometer or the like for calculation of roughness.

As illustrated in FIG. 2, the via hole conductor 4 may include a third region 53 being in contact with the second insulating layer 22 and positioned in a direction along the first surface 2a in a peripheral edge portion adjacent to the land conductor 5. The third region 53 thus provided includes a surface not limited in arithmetic mean roughness. The surface of the third region 53 may be larger in arithmetic mean roughness than the surface of the second region 52 or the like. The surface of the third region 53 corresponds to a surface on which the third region 53 is in contact with the second insulating layer 22.

When the surface of the third region 53 is larger in arithmetic mean roughness than the surface of the second region 52, exemplarily in a region including a boundary between the side surface of the via hole conductor 4 and the third region where stress is likely to concentrate, the via hole conductor 4 and the second insulating layer 22 are improved in intimate contact properties therebetween and electrical signal transmission performance is improved due to relatively small arithmetic mean roughness on the surface of the second region 52 where stress is less likely to concentrate. This enables provision of the wiring board 10 that achieves excellent intimate contact properties between the via hole conductor 4 and the second insulating layer 22 and excellent electrical signal transmission performance.

The organic film 7 is not limited in thickness L as long as the organic film 7 covers the surface of the second region 52. The organic film 7 may have the thickness L exemplarily 10 nm or more and 100 nm or less. The thickness L of the organic film 7 may be even, or may be uneven as illustrated in FIG. 3. FIG. 3 is an enlarged explanatory view of a region III indicated in FIG. 2 according to an embodiment. When the thickness L of the organic film 7 is uneven, the organic film 7 is increased in surface area. This improves intimate contact properties between a resin and the organic film. When the thickness L of the organic film 7 is uneven , the thickness L may be uneven within the above range and the thickest portion and the thinnest portion may have a difference of exemplarily 50 nm or less. The thickness L of the organic film 7 can be defined as a length from the land conductor 5 to the second insulating layer 22 in the thickness direction of the wiring board 10 on an upper surface or the like of the land conductor 5, and can be defined as a length from the land conductor 5 to the second insulating layer 22 in the direction along the first surface 2a on a side surface of the land conductor 5.

As illustrated in FIG. 3, when the second insulating layer 22 includes an insulating filler 8, part of the insulating filler 8 may be in contact with the organic film 7. Although the insulating filler 8 is not in intimate contact with the organic film 7, the organic film 7 and the resin achieve excellent intimate contact therebetween. The insulating filler 8 and the organic film 7 in contact with each other have point contact, so that adhesion deterioration can be reduced by adhesion between the organic film 7 and the resin in a region other than such a contact point.

In the wiring board 10 according to an embodiment, the land conductor 5 and the via hole conductor 4 are not limited in terms of forming method, and are formed through the following procedure or the like. Initially, the conductor layer 3 including the land conductor 5 is formed on the first surface 2a of the first insulating layer 21 in accordance with a semiadditive method. The land conductor 5 and the conductor layer 3 are configured as described above and will not be described in detail.

Subsequently, the organic film 7 covers the surface of the land conductor 5 formed on the first surface 2a of the first insulating layer 21. The organic film 7 is formed by adsorption of a copper complex or the like and coordinate bonding with copper. The organic film 7 is configured as described above and will not be described in detail.

After the surface of the land conductor 5 is covered with the organic film 7, the second insulating layer 22 is formed to cover the first surface 2a and the surface of the organic film 7. The second insulating layer 22 is formed by disposing a resin film or the like as a material for the second insulating layer 22 to cover the first surface 2a and the surface of the organic film 7 at reduced pressure and heating and pressurizing the resin film.

Subsequently, the via hole 23 is formed in the second insulating layer 22. The via hole 23 is not limited in terms of forming method, and can be formed by means of a laser beam or the like. The via hole 23 is formed to penetrate from the second surface 2b of the second insulating layer 22 to the land conductor 5. A laser beam is applied to remove the organic film 7 positioned in the first region 51 of the land conductor 5. The via hole 23 thus includes a bottom surface provided with the land conductor 5 exposed instead of the organic film 7. Desmearing may be executed as necessary, for removal of any smear generated during laser beam application. Etching may be optionally executed to trim a surface of the first region 51. For example, such etching is executed to form a region including the third region 53 being in contact with the second insulating layer 22 and positioned in the direction along the first surface 2a in the peripheral edge portion adjacent to the land conductor 5 of the via hole conductor 4. Moreover, desmearing may be executed again to remove the organic film 7 remaining on the second insulating layer 22 in the region including the third region 53. Desmearing in this case may be executed under a weaker condition in comparison to smear removal. The inner wall surface of the via hole 23 is substantially equal in arithmetic mean roughness to the side surface of the via hole conductor 4.

Subsequently, the first conductor layer 41 is formed on the inner wall surface of the via hole 23. The first conductor layer 41 is formed by electroless plating, sputtering, or the like. The first conductor layer 41 is configured as described above and will not be described in detail.

Subsequently, the second conductor layer 42 is formed on a surface of the first conductor layer 41. The second conductor layer 42 is formed by electroplating or the like. The second conductor layer 42 is configured as described above and will not be described in detail.

As illustrated in FIG. 2, the first conductor layer 41 and the second conductor layer 42 are formed also in a circumferential edge portion of an opening of the via hole 23 in the second surface 2b during formation of the via hole conductor 4, so that the conductor layer 3 (the first conductor layer 41 and the second conductor layer 42) positioned on the second surface 2b serves as the land conductor 5. Regarding the land conductor 5 positioned on the second surface 2b as a land positioned on the first surface 2a, these procedures are repeated a desired number of times.

Description is made next to a mount structural body according to the present disclosure with reference to FIG. 1. In an embodiment, a mount structural body includes the wiring board 10 according to an embodiment, and the electronic component E positioned in a mount region for the wiring board 10.

FIG. 1 illustrates a state where the wiring board 10 and the electronic component E are disconnected from each other. An electronic component connection pad (part of the buildup conductor layer positioned on the surface of on one of the buildup layers) exposed from the opening of the solder resist 6 positioned on one of surfaces of the wiring board 10 and the electrode of the electronic component E are connected via the solder S or the like to obtain the mount structural body according to an embodiment. Examples of the electronic component E include a semiconductor integrated circuit and an optoelectronic element. In the mount structural body according to an embodiment, the electronic component E may be connected via the solder S also to another pad (part of the buildup conductor layer positioned on the surface of on the other one of the buildup layers) exposed from the opening of the solder resist 6 positioned on the other one of surfaces of the wiring board 10. The other pad of the wiring board 10 may alternatively be connected to a motherboard or the like via the solder S.

The embodiments of the present disclosure have been described above. However, the present disclosure is not limited to the embodiments described above and can be modified and improved in various manners within the scope of the present disclosure recited in (1) to (8) hereinafter.

(1) The present disclosure provides a wiring board including a first insulating layer, a conductor layer, a second insulating layer, and a via hole conductor. The first insulating layer includes a first surface. The conductor layer is positioned on the first surface and at least includes a land conductor. The second insulating layer is positioned on the first surface, includes a second surface positioned opposite to the first insulating layer, and includes a via hole penetrating from the second surface to the land conductor. The via hole conductor is positioned in the via hole and is in contact with the land conductor. The land conductor includes a first region in contact with the via hole conductor, and a second region other than the first region. The second region and the second insulating layer interpose an organic film.

(2) In the wiring board according to (1) described above, the first region includes a concave portion shaped to be concave toward the first surface.

(3) In the wiring board according to (1) or (2) described above, the conductor layer further includes a wiring conductor positioned on the first surface, and each of the wiring conductor and the second region includes a surface having arithmetic mean roughness of 100 nm or more and 200 nm or less.

(4) In the wiring board according to any one of (1) to (3) described above, the organic film has an uneven thickness.

(5) In the wiring board according to any one of (1) to (4) described above, the second insulating layer includes an insulating filler, and part of the insulating filler is in contact with the organic film.

(6) In the wiring board according to any one of (1) to (5) described above, the via hole conductor includes a side surface larger in arithmetic mean roughness than a surface of the second region.

(7) In the wiring board according to any one of (1) to (6) described above, the via hole conductor includes a third region being in contact with the second insulating layer and positioned in a direction along the first surface in a peripheral edge portion adjacent to the land conductor, and the third region includes a surface that is in contact with the second insulating layer and that is larger in arithmetic mean roughness than a surface of the second region in contact with the organic film.

(8) The present disclosure provides the wiring board according to any one of (1) to (7) described above, and an electronic component connected to the wiring board.

What is claimed is:

1. A wiring board comprising:
a first insulating layer including a first surface;
a conductor layer positioned on the first surface and at least including a land conductor;
a second insulating layer positioned on the first surface, including a second surface positioned opposite to the first insulating layer, and including a via hole penetrating from the second surface to the land conductor; and
a via hole conductor positioned in the via hole and being in contact with the land conductor; wherein
the land conductor includes a first region in contact with the via hole conductor, and a second region other than the first region, and
the second region and the second insulating layer interpose an organic film.

2. The wiring board according to claim 1, wherein
the first region includes a concave portion shaped to be concave toward the first surface.

3. The wiring board according to claim 1, wherein
the conductor layer further includes a wiring conductor positioned on the first surface, and
each of the wiring conductor and the second region includes a surface having arithmetic mean roughness of 100 nm or more and 200 nm or less.

4. The wiring board according to claim 1, wherein
the organic film has an uneven thickness.

5. The wiring board according to claim 1, wherein
the second insulating layer includes an insulating filler, and
part of the insulating filler is in contact with the organic film.

6. The wiring board according to claim 1, wherein
the via hole conductor includes a side surface larger in arithmetic mean roughness than a surface of the second region.

7. The wiring board according to claim 1, wherein
the via hole conductor includes a third region being in contact with the second insulating layer and positioned in a direction along the first surface in a peripheral edge portion adjacent to the land conductor, and
the third region includes a surface that is in contact with the second insulating layer and that is larger in arithmetic mean roughness than a surface of the second region.

8. A mount structural body comprising the wiring board according to claim 1, and an electronic component connected to the wiring board.
